(19) United States
(12) Patent Application Publication
(10) Pub. No.: US 2024/0105525 A1
(43) Pub. Date: Mar. 28, 2024

(54) Test Architecture for High Throughput Testing of Pixel Driver Chips for Display Application

(71) Applicant: Apple Inc., Cupertino, CA (US)

(72) Inventors: Imran Hashim, Saratoga, CA (US); Xiang Lu, Campbell, CA (US); Stanley B. Wang, Cupertino, CA (US); Xuchun Liu, Foster City, CA (US); Mahdi Farrokh Baroughi, Santa Clara, CA (US); Yongjie Jiang, Santa Clara, CA (US); Hopil Bae, Sunnyvale, CA (US); Hasan Akyol, Mountain View, CA (US); Baris Posat, Saratoga, CA (US); John T. Wetherell, San Jose, CA (US); Lei Wu, San Jose, CA (US)

(21) Appl. No.: 18/358,559

(22) Filed: Jul. 25, 2023

Related U.S. Application Data
(60) Provisional application No. 63/376,974, filed on Sep. 23, 2022.

(51) Int. Cl. G09G 3/32; H01L 25/075; H01L 33/62

(52) U.S. Cl. CPC G09G 3/32; H01L 25/0753; H01L 33/62; H01L 2933/0066

(57) ABSTRACT

Test structures and methods of testing pixel driver chip donor wafers are described. In an embodiment, a redistribution layer is formed over a pixel driver chip donor wafer and probed to determine known good dies, followed by removal of the RDL. In other embodiments, test routing is formed in the pixel driver chip using a polycide material or doped region in the semiconductor wafer.

### RELATED APPLICATIONS

This application claims the benefit of priority of U.S. Provisional Application No. 63/376,974 filed Sep. 23, 2022, which is incorporated herein by reference.

### BACKGROUND

### Field

Embodiments described herein relate to design-for-test architecture. More particularly, embodiments relate to design-for-test architectures for pixel driver chip donor wafers for micro LED displays.

### Background Information

Micro light emitting diode (LED), also known as μLED, is an emerging flat panel display technology. The μLED-based display panel includes arrays of microscopic LEDs forming the individual pixel elements. The pixel elements in turn can be operated with a backplane formed of thin film transistors (TFT), metal-oxide semiconductor field-effect transistor (MOSFET) technology, or an array of pixel driver chips where local arrays of the μLEDs may each be driven by a corresponding pixel driver chip, which may also have microscopic dimensions on the order of the μLEDs to multiple pixel groups. It has been proposed to fabricate a display panel backplane with redundant uLEDs and redundant pixel driver chips to compensate for potential defects associated with the fabrication and pick-and-place bonding technologies.

### SUMMARY

In accordance with embodiments, methods of testing pixel driver chip donor wafers are described utilizing both temporary and permanent test structures. In an embodiment, a temporary redistribution layer (RDL) is formed over a pixel driver chip donor wafer and probed to determine known good dies, followed by removal of the RDL. In an embodiment, a method of testing a pixel driver chip donor wafer for known good dies includes forming an array of pixel driver chip areas in a wafer, forming a back-end-of-the-line (BEOL) build-up structure over the array of pixel driver chip areas, forming a redistribution layer (RDL) over the BEOL build-up structure, the RDL including an array of reticle areas; each reticle area encompassing a corresponding sub-array of pixel driver chip areas and including a sub-area of test pads, probing each sub-area of test pads to test the corresponding sub-array of pixel driver chip areas, and removing the RDL.

In other embodiments, permanent test routing is formed in the pixel driver chip using a polycide material or doped region in the semiconductor wafer. In an embodiment a pixel driver chip includes a semiconductor substrate including a device region, a BEOL build-up structure on the semiconductor substrate, the BEOL build-up structure including a plurality of metal wiring layers, and a plurality of landing pads, chip sidewalls spanning the semiconductor substrate and the BEOL build-up structure, and an electrical connection extending to a first sidewall of the chip sidewalls, wherein the electrical connection is formed of a polycide material or doped region of the semiconductor substrate.

### BRIEF DESCRIPTION OF THE DRAWINGS

FIG. 1 is a schematic top view illustration of a donor wafer and reticle area including an array of pixel driver chip areas and test pad area in accordance with an embodiment.

FIG. 2 is a process flow for a method of testing a donor wafer including an array of pixel driver chip areas in accordance with an embodiment.

FIG. 3 is a schematic cross-sectional side view illustration of a redistribution layer (RDL) formed over a donor wafer reticle area including a sub-array of pixel driver chip areas and a sub-array of test pads in accordance with an embodiment.

FIG. 4 is a schematic top view illustration of columnar connection layout for reticle probe pads in accordance with an embodiment.

FIG. 5 is a schematic top view illustration of row connection layout for reticle probe pads in accordance with an embodiment.

FIG. 6 is a schematic top view illustration of shared global connection in accordance with an embodiment.

FIG. 7 is a circuit diagram of a scan-chain connection between a pixel driver chip area and a DFT controller in accordance with an embodiment.

FIG. 8 is an analog pixel circuit or unit cell of a pixel driver chip according to an embodiment.

FIG. 9 is a schematic cross-sectional side view illustration of diffused electrical connections between adjacent pixel driver chip areas in accordance with an embodiment.

FIG. 10 is a schematic cross-sectional side view illustration of polycide electrical connections between adjacent pixel driver chip areas in accordance with an embodiment.

FIG. 11 is a schematic top view illustration of a reticle area including a plurality of pixel driver chip areas serially connected with polycide or diffused test routing in accordance with an embodiment.

FIG. 12 is a schematic top view illustration of a reticle area including a plurality of pixel driver chip areas connected with rows and columns of polycide or diffused test routing in accordance with an embodiment.

FIG. 13 is a schematic top view illustration of a reticle area including a plurality of pixel driver chip areas connected with metal test routing and polycide bridges in accordance with an embodiment.

### DETAILED DESCRIPTION

Embodiments describe design-for-test (DFT) architectures, and methods of testing an array of pixel driver chips on a donor wafer. Specifically, the pixel driver chips may be designed for μLED-based display panels. Testing may be performed on the donor wafer prior to singulation of the pixel driver chips to qualify the pixel driver chips prior to assembly into the μLED-based display panels. In this manner only known good pixel driver chips are integrated into a display, mitigating display yield losses that could otherwise be associated with defective pixel driver chips, for example, obtained from outlier donor wafers or process variation across a donor wafer. Token-based control schemes for the pixel driver chip areas can also be leveraged in order to select entire rows and/or columns within a reticle area.

In one aspect, pixel driver chips with dimensions on the order of the μLEDs to multiple pixel groups, along with the number of landing pads for operation can require the pixel driver chip landing pads to be insufficiently large for landing of test probes. Furthermore, the number of pixel driver chips per donor wafer can be in the range of hundreds of thousands which can take a prohibitively long time for testing of each wafer during manufacturing. In accordance with embodiments, DFT architectures and methods are described in which pixel driver chips within each reticle field are connected together through an interconnect such as a sacrificial metal layer, polycide, or diffusion region and tested together with larger test pads, utilizing space at the edge of the reticle field which can also be used to provide power and ground signal, etc. In this manner it may be possible to test all pixel driver chips in one reticle field in one touchdown, and to test all pixel driver chips on a donor wafer in significantly reduced time.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “over”, “to”, “between”, “spanning” and “on” as used herein may refer to a relative position of one layer with respect to other layers. One layer “over”, “spanning” or “on” another layer or bonded “to” or in “contact” with another layer may be directly in contact with the other layer or may have one or more intervening layers. One layer “between” layers may be directly in contact with the layers or may have one or more intervening layers.

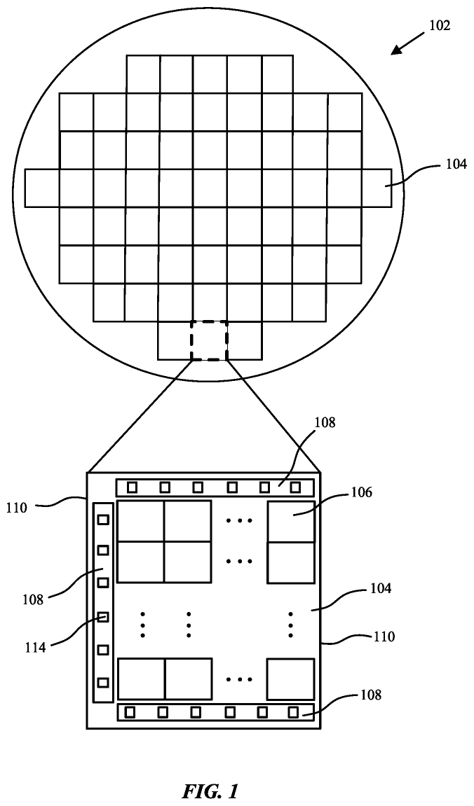

Referring now to FIG. 1 a cross-sectional side view illustration is provided of a donor wafer 102 including an array of reticle areas 104, each reticle area 104 including a sub-array of pixel driver chip areas 106 and test pad area 108 in accordance with an embodiment. For example, the test pad area 108 including test pads 114 can be along a single edge 110 of the reticle area 104 or a plurality of edges 110, including all edges/sides.

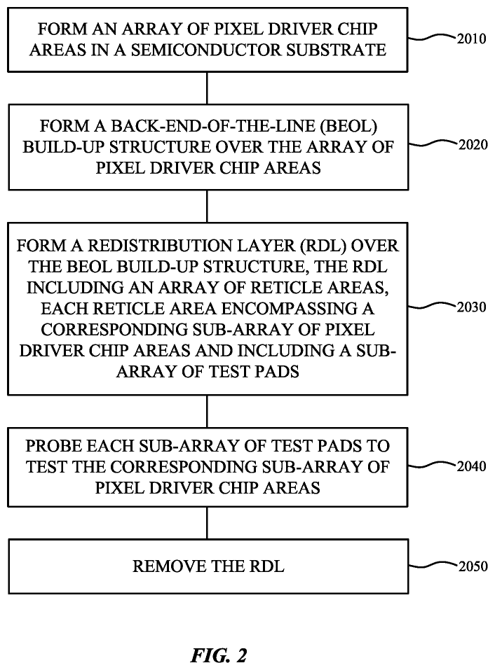

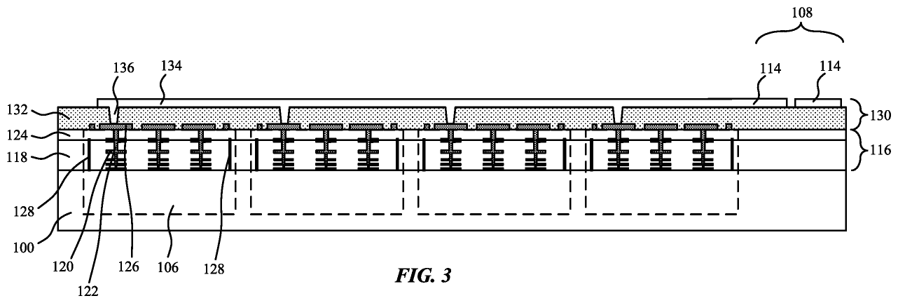

FIG. 2 is a process flow for a method of testing a donor wafer 102 including an array of pixel driver chip areas 106 in accordance with an embodiment. FIG. 3 is a schematic cross-sectional side view illustration of a redistribution layer (RDL) formed over a donor wafer 102 reticle area 104 including a sub-array of pixel driver chip areas 106 and a sub-array of test pads 114 in accordance with an embodiment. In interest of clarity and conciseness, the description of the process flow of FIG. 2 is made with reference to the structure of FIG. 3.

At operation 2010 an array of pixel driver chip areas 106 is formed in a semiconductor substrate 100. A back-end-of-the-line (BEOL) build-up structure 116 is then formed over the array of pixel driver chip areas 104 at operation 2020. The BEOL build-up structure 116 may include various dielectric layers 118 (e.g. oxides, low-k materials, etc.) and metal wiring layers 120 connected with vias 122. Metal wiring layers 120 may be referred to as M1-Mz, with M1 being a lower metal layer and Mz being an upper metal layer. In accordance with embodiments, Mz metal wiring layer can also be used for metal routing at the reticle edge. The BEOL build up structure 116 may additionally include a top passivation layer 124 (e.g. nitride) and an array of landing pads 126. As shown, the BEOL build-up structure 116 can further include a perimeter (metal) seal ring 128. Together the perimeter seal ring 128 and top passivation layer 124 can provide mechanical protection and prevent the ingress of moisture, etc.

At operation 2030 a redistribution layer (RDL) 130 is then formed over the BEOL build-up structure 116. Referring briefly back to FIG. 1 the RDL 130 is formed over the entire array of reticle areas 104, with each reticle area encompassing a corresponding sub-array of pixel driver chip areas 106 and a sub-array of test pads 114. The RDL 130 can be formed in the same facility as the BEOL build-up structure or alternatively in a packaging facility using different deposition techniques. As shown, the RDL 130 similarly include one or more dielectric layers 132 and one or more metal wiring layers 134 connected with vias 136, as well as the sub-arrays of test pads 114. The test pads 114 may have a larger area than landing pads 126 to facilitate probing. In accordance with embodiment, metal routing in upper metal layer(s), such a Mz metal wiring layer 120, can help reduce wiring required in the RDL 130. For example, this may facilitate use of a single metal wiring layer 134 RDL 130. This may reduce process time, and overall cost.

The sub-arrays of test pads 114 can be arranged in test pad areas 108 that are optionally laterally outside of the pixel driver chip areas 106. This may facilitate row/column testing processes at operation 2040 where each sub-array of test pads is probed to test the corresponding sub-arrays of pixel driver chip areas 106 for known good dies (KGD). Once KGD testing is complete the RDL 130 can be removed at operation 2050, followed by cleaning and singulation of individual pixel driver chips for subsequent integration into an optoelectronic module. For example, singulation may include etching through the wafer and the BEOL build-up structure using a suitable technique such as dry reactive ion etching (DRIE).

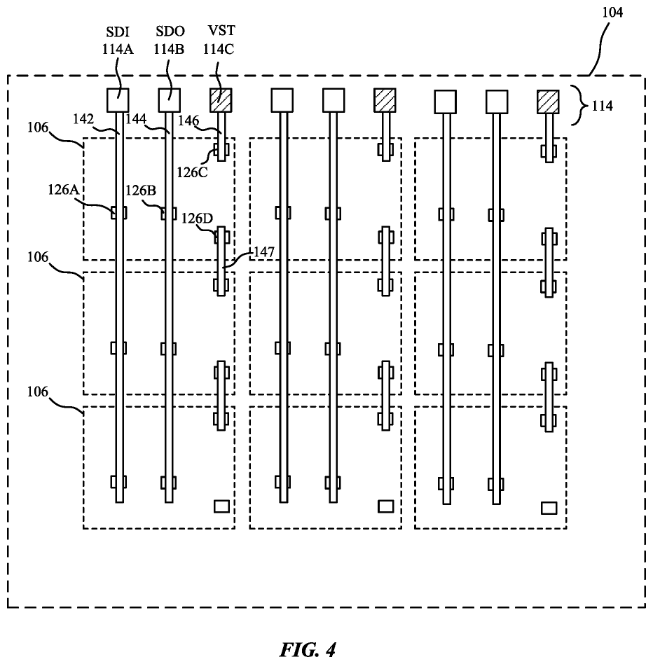

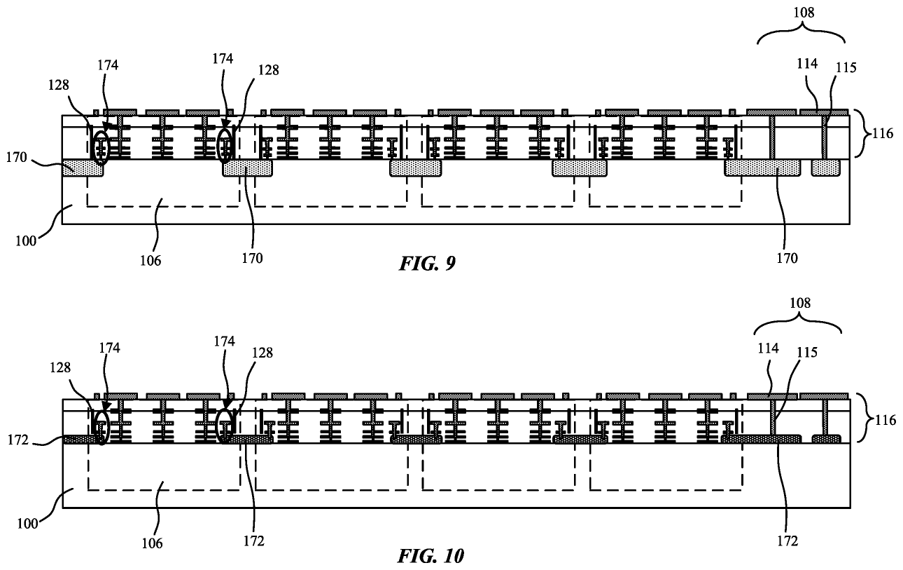

Referring now to FIGS. 4-6 schematic top view illustrations are provided for various columnar and row routing connections in accordance with embodiments. For example, this may be routing within the RDL 130 which is connected to landing pads 126 for each pixel driver chip area 106. It is to be appreciated that while FIGS. 4-6 are illustrated separately, this is for clarity, and that the routings for each of FIGS. 4-6 can be combined. Furthermore, the routings illustrated are exemplary and actual implementation may be more complex. Lastly, the routings illustrated are not limited to the RDL 130 and may be otherwise provide, such as with diffusion layers, polycide layers, and metal wiring layers within the BEOL build-up structure as will be described in further detail with regard to FIGS. 9-13.

FIG. 4 is a schematic top view illustration of columnar connection layout for reticle probe pads in accordance with an embodiment. The test pads 114 shown in FIG. 4 can be for a variety of signals such as data, data clock, DFT scan enable, DFT program enable, vertical selection token (VST) pixel clock, pixel driver chip mode, configuration update, etc. In the exemplary embodiment illustrated, a scan data in (SDI) and scan data out (SDO) signals can be applied to test pads 114A and 114B, respectively. Data line column 142 can be connected to a landing pad 126A for each pixel driver chip area 106 to input a scan data signal. Similarly, data line column 144 can be connected to a landing pad 126B for each pixel driver chip. VST signals can be applied to test pads 114C, with pixel driver chip areas 106 connected through a daisy-chain within a VST line column 146 formed of tie bars 147 connecting landing pads 126C and 126D of adjacent pixel driver chip areas 106.

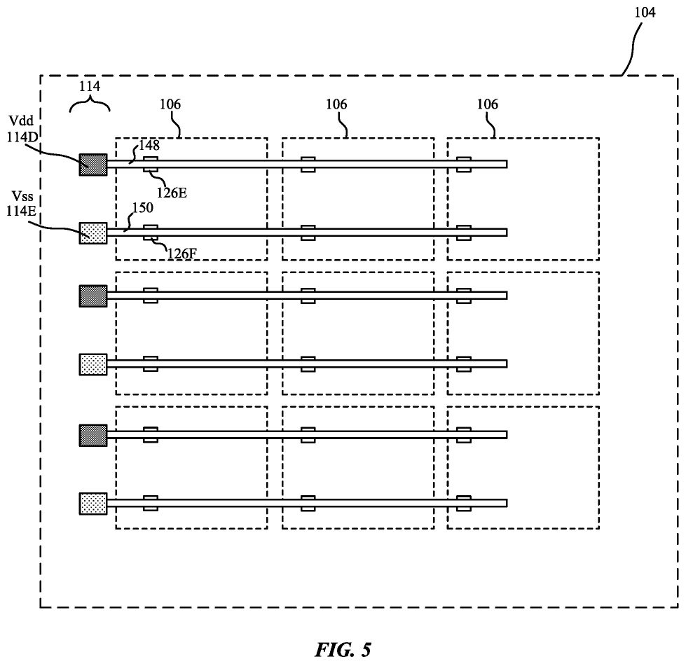

FIG. 5 is a schematic top view illustration of row connection layout for reticle probe pads in accordance with an embodiment. In accordance with embodiments, power and ground can potentially be shared through horizontal row connections. Power and ground may be shared by all pixel driver chip areas 106 in one reticle area 104. In the exemplary embodiment illustrated, a power (Vdd) and ground (Vss) signals can be applied to test pads 114D and 114E, respectively. Power line rows 148 can connect to a corresponding row of pixel driver chip areas 106 and landing pads 126E. Similarly ground line rows 150 can connect to a corresponding row of pixel driver chip areas 106 and landing pads 126F.

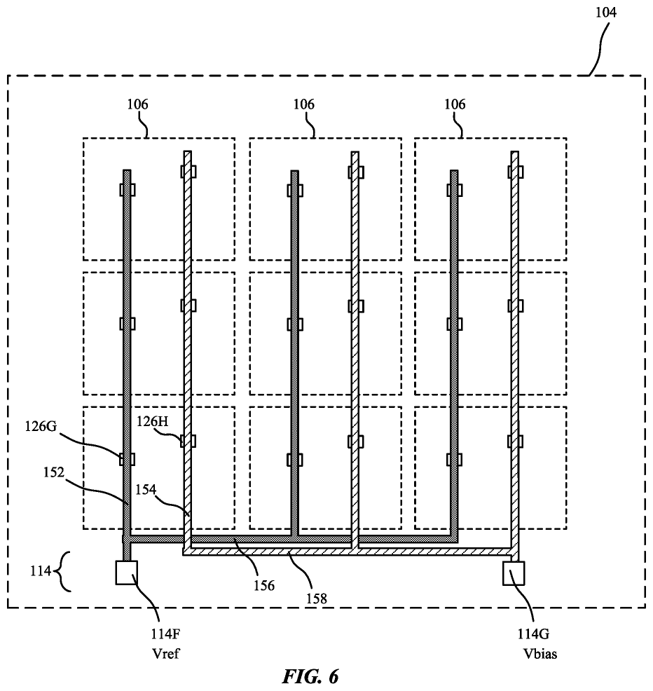

FIG. 6 is a schematic top view illustration of shared global connection in accordance with an embodiment. The test pads 114 shown in FIG. 6 can be for a variety of signals such as bias voltage (Vbias), reference voltage (Vref), initialization voltage (Vini), etc. The global signals may be shared by multiple columns through a shorting bar at the reticle area 104 edge. In the exemplary embodiment illustrated, a Vref and Vbias signals can be applied to test pads 114F and 114G, respectively. Global reference voltage line columns 152 can connect to a corresponding column of pixel driver chip areas 106 and landing pads 126G. Global bias voltage line columns 154 can connect to a corresponding column of pixel driver chip areas 106 and landing pads 126H. In the illustrated embodiment, the plurality of global reference voltage line columns 152 is divided into a plurality of sets, each set connected to a different global reference voltage test pad 114F. This may be achieved with a shorting bar 156. Similarly, the global vias voltage line columns 154 can be connected with a shorting bar 158, and test pad 114G. While not similarly illustrated, the power and ground routing in FIG. 5 can be similarly connected and shared.

In an exemplary testing procedure token-based control schemes for the pixel driver chip areas can be leveraged, where adjacent pixel driver chip areas in a column are connected through a daisy-chain. Data, data clock, and VST probing pads can be dedicated for each column, and global signals can be shared by multiple columns with a shorting bar at the reticle area edge. Power and ground can additionally be shared by all pixel driver chip areas within one reticle area.

In an embodiment, the wafer 102 may be tested one reticle area 104 at a time. Testing of each reticle area 104 can include broadcasting a plurality of cycles of scan-data in (SDI) to all pixel driver chip areas 106 in a row of pixel driver chip areas, producing a scan-data out (SDO) data stream for each pixel driver chip area, comparing a downstream version of the SDO data stream for each pixel driver chip areas with an expected data stream, storing values of the compared data streams (e.g. with the stored values (e.g. 0, 1) indicative if an error is present in the compared data streams), and shifting out the stored values as the DFT output.

In operation, a DFT controller may first send VST signals to each test pad 114C to turn on a specified row, or rows, and broadcast pixel driver configuration data across a row of pixel driver chip areas 106. Thus, all pixel driver chip areas 106 in the same row may be tested at once, and receive the same signal.

The scan-data out from all pixel drivers in the same column share a common scan-data out (SDO) bus to send the data back to the DFT controller. The SDO bus lines may be data line columns 144. Likewise, the SDI bus lines may be data line columns 142. In an embodiment the data line columns are bi-directional, and the SDO and SDI signals share the same data line column.

Referring now to FIG. 7, an illustration is provided of the scan-chain connection between a pixel driver chip area 106 and DFT controller 101. As shown in the scan-chain, pipelined positive triggered flip-flops 160 and negative triggered flip-flops 162 are located near SDI output terminals of the DFT controller 101, and SDO input terminals of the DFT controller. SDI data line column 142 and SDO data line column 142 routing on the wafer may be through routing of the pixel driver scan connections, to landing pads 126A, 126B on the pixel driver chip areas 106 chips as SDI and SDO input and output terminals. The shift path 165 within a pixel driver chip area 106 may include a chain of positive triggered flip-flops 166, including a first positive triggered flip-flop 160 coupled to the SDI terminal. A clock gater 168 is coupled to a last positive triggered flip-flop in the chain of positive triggered flip-flops 166 to covert logical 1 non-return-to-zero (NRZ) output Q1 from the last positive triggered flip-flop to a pulse (P) return-to-zero (RZ) output Q2 from the clock gater 168. Simplified illustrations of the positive triggered flip-flops 166 are provided to show the scan input (SI), output (Q), and scan clock (triangle). Simplified clock gater 168 illustration includes enable (E), test enable (TE), enable clock (ECK), and scan clock (triangle). As shown, the output Q1 is fed to the enable (E) input of the clock gater 168. As shown, the flip-flops 166 in the scan-chain are negatively triggered, and the clock gater 168 is inserted in the shift path between the last flip-flop 166 and the SDO data line column 142.

In an embodiment, a method of testing a pixel driver chip area 106 includes broadcasting a plurality of cycles of scan-data in (SDI) 210 to a pixel driver chip area, generating a square waveform output signal (e.g. 0, 1) from a chain of positive triggered flip-flops 166, receiving the square waveform output signal with a clock gater 168 in the pixel driver chip area, and transmitting a pulse P signal from the clock gater 168 to a negative triggered flip-flop 162 in DFT controller 101, and generating a square waveform output signal with the negative triggered flip-flop 162 in the DFT controller 101. In an embodiment, an automatic test pattern generation (ATPG) model is run in which the clock gater 168 is modeled as a positive triggered flip-flop 160.

While the exemplary embodiments thus far have illustrated testing capability with digital data SDI/SDO scans embodiments are not so limited. For example, analog testing can also be performed.

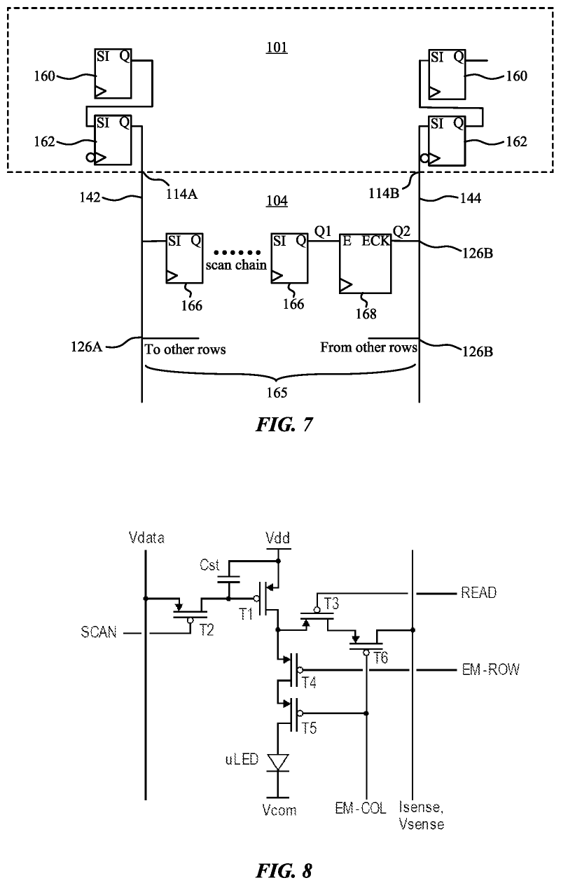

Referring to FIG. 8, an exemplary 6 transistor (6T) and 1 storage capacitor (1C) pixel circuit is illustrated which may include Cst: storage capacitor for holding the data voltage, T1: current driving transistor, T2: switch for sample and hold, T3: switch for sense column line connection, T4: switch (row) for turning the emission on and off, T5: switch (column) for turning the emission on and off, and T6: switch (column) for selecting sense column. In one embodiment, T6 may be part of a readout column select. In one embodiment, the digital signals are SCAN: generated by row driver (e.g., to sample Vdata), READ: generated by row driver (e.g., to connect a pixel circuit to sense column line), EM-ROW (e.g., to emit light if EM-COL is also active), and EM-COL (e.g., to emit light if EM-ROW is also active). In one embodiment, the analog signals are Vdata (input): analog data to be sampled and which sets the gate voltage of the current driving transistor T1, Isense (output): when the read-out switch T3 and switches T5 and T6 are closed and the emission switch T4 is open, the current from T1 may be flowing through the sense column line and may be measured outside the chip, and Vsense (output): when the read-out switch T3 and switches T5 and T6 are closed and both emission switches are closed, the current from T1 may flow through the display element (e.g., μLED) and the voltage level on the display element (e.g., μLED anode, minus voltage drop of T4 and T5) may be measured from the sense column line. In accordance with embodiments, the pixel driver chip areas can include a variety of digital configurations, analog configurations, and combinations thereof.

Referring now to FIGS. 9-10, schematic cross-sectional side view illustrations similar to FIG. 3 are provided where instead building a temporary RDL 130 for test routing, the test routing can be integrated into the diffused electrical connections 170 (FIG. 9) or polycide electrical connections 172 (FIG. 10). For example, the diffused electrical connections 170 can be provided by diffusing and/or implanting a dopant into the semiconductor substrate 100. The diffused electrical connections 170 may tunnel in the semiconductor substrate 100 (e.g. silicon), possibly below active devices. The polycide electrical connections 172 (e.g. silicide on top of polysilicon) can be formed on top of the semiconductor substrate 100.

The diffused electrical connections 170 or polycide electrical connections 172 may be used in place of the temporary RDL to provide test routing. Furthermore, diffused electrical connections 170 and polycide electrical connections 172 are compatible with DRIE etching used for singulation of the pixel driver chips. More specifically, DRIE etching can be used to etch through silicon, polysilicon, oxide, polycide, though not for metals. As such, singulation is not performed through metal routing layers, though the diffused electrical connections 170 and polycide electrical connections 172 may extend to a singulated sidewall of a pixel driver chip.

Still referring to FIGS. 9-10, the diffused electrical connections 170 and polycide electrical connections 172 can additionally be connected with metal trace routings 174, which can also be inside the perimeter seal rings 128. In this manner, metal trace routings can still be used to provide long connections and connect to the diffused electrical connections 170 and polycide electrical connections 172 at localized singulation regions. The metal trace routings may optionally be connected with the device region, or not be connected to the device region of the pixel driver chip areas. In the illustrated embodiments, the diffused electrical connections 170 and polycide electrical connections 172 extend underneath the perimeter metal seal ring 128 to provide chip-to-chip connections for the test routing.

In the embodiments illustrated in FIGS. 9-10 the test pad area 108 is outside of the pixel driver chip areas 106. Electrical connection to the test pads 114 can be made with vertical interconnects 115 formed of stacked vias 122 and optionally metal wiring layers 120.

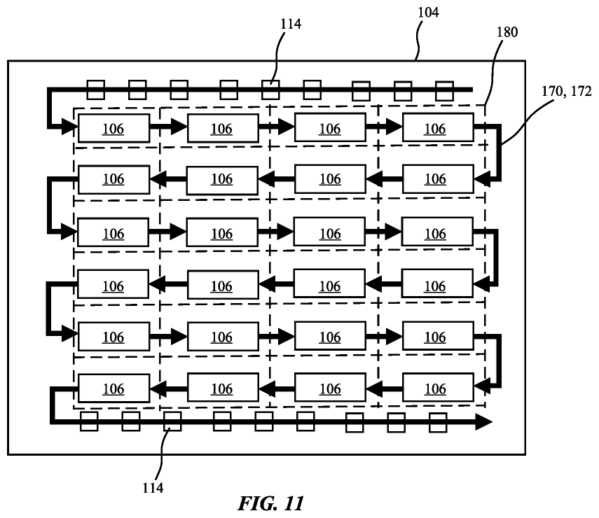

Referring now to FIG. 11 a schematic top view illustration is provided of a reticle area 104 including a plurality of pixel driver chip areas 106 serially connected with polycide or diffused test routing in accordance with an embodiment. As shown, the serial connections can reduce the number of test pads 114 needed. In an embodiment adjacent pixel driver chip areas 106 can be shorted with switches for high throughput analog testing. Once singulated along the dotted lines, the diffused electrical connections 170 or polycide electrical connections 172 can extend to one or more chip sidewalls 180 (formed by singulation).

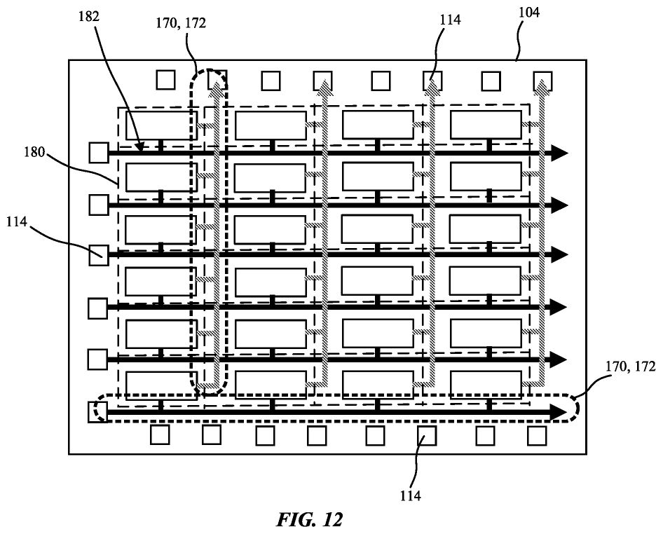

FIG. 12 is a schematic top view illustration of a reticle area 104 including a plurality of pixel driver chip areas 104 connected with rows and columns of polycide or diffused test routing in accordance with an embodiment. In this configuration, individual pixel driver chip areas 106 can be tested. Furthermore, in this configuration, where polycide is used, a singulated pixel driver chip may include a floating polycide electrical connection 172, indicated as trace 182, may be present adjacent a sidewall 180 of the pixel driver chip.

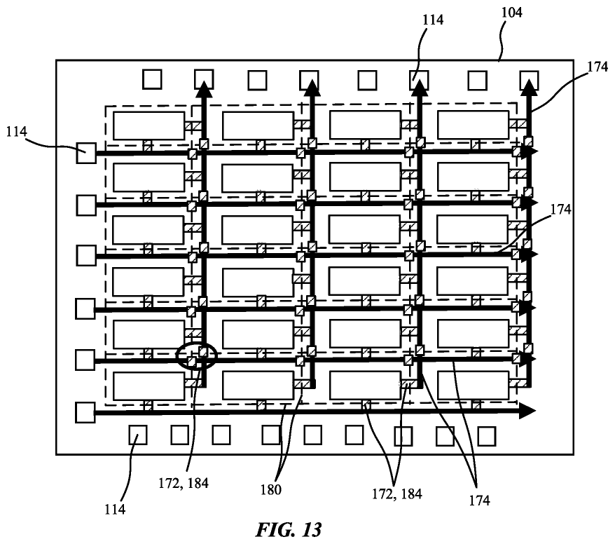

FIG. 13 is a schematic top view illustration of a reticle area 104 including a plurality of pixel driver chip areas 106 connected with metal test routing and polycide bridges in accordance with an embodiment. In this configuration, metal trace (test) routings 174 can provide a bulk of the test routing, while the polycide electrical connection 172 areas can function as short local interconnects as polycide bridges 184 to provide a material that can be etched for singulation purposes. In this manner, the metal trace routings 174 do not extend to the chip sidewalls 180, and instead polycide bridges 184 can extend to the chip sidewalls 180.

In utilizing the various aspects of the embodiments, it would become apparent to one skilled in the art that combinations or variations of the above embodiments are possible for testing a pixel driver chip donor wafer. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. A method comprising:
forming an array of pixel driver chip areas in a wafer;
forming a back-end-of-the-line (BEOL) build-up structure over the array of pixel driver chip areas;
forming a redistribution layer (RDL) over the BEOL build-up structure, the RDL including an array of reticle areas; each reticle area encompassing a corresponding sub-array of pixel driver chip areas and including a sub-area of test pads;
probing each sub-area of test pads to test the corresponding sub-array of pixel driver chip areas; and
removing the RDL.

2. The method of claim 1, further comprising etching through the wafer and the BEOL build-up structure after removing the RDL to singulate an array of pixel driver chips.

3. The method of claim 1, wherein each reticle area of the RDL includes a plurality of data line columns, wherein each data line column is connected to a corresponding column of pixel driver chip areas.

4. The method of claim 3, wherein each data line column is electrically connected to each pixel driver chip area of the corresponding column of pixel driver chip areas.

5. The method of claim 1, wherein each reticle of the RDL includes a plurality of vertical select token (VST) line columns, wherein each VST line column is connected to a corresponding column of pixel driver chip areas.

6. The method of claim 5, wherein each VST line column is non-continuous and includes a plurality of tie bars, each tie bar connecting adjacent pixel driver chip areas in the column of pixel driver chip areas.

7. The method of claim 1, wherein each reticle of the RDL includes a plurality of power line rows, wherein each power line row is connected to a corresponding row of pixel driver chip areas.

8. The method of claim 1, wherein each reticle area of the RDL includes a plurality of global reference voltage line columns, wherein each global reference voltage line column is connected to a corresponding column of pixel driver chip areas.

9. The method of claim 8, wherein the plurality of global reference voltage line columns is divided into a plurality of sets, each set connected to a different global reference voltage test pad.

10. A pixel driver chip comprising:
a semiconductor substrate including a device region;
a back-end-of-the-line (BEOL) build-up structure on the semiconductor substrate, the BEOL build-up structure including a plurality of metal wiring layers, and a plurality of landing pads;
chip sidewalls spanning the semiconductor substrate and the BEOL build-up structure; and
an electrical connection extending to a first sidewall of the chip sidewalls, wherein the electrical connection is formed of a polycide material or doped region of the semiconductor substrate.

11. The pixel driver chip of claim 10, wherein the BEOL build-up structure further comprises a perimeter metal seal ring, and the electrical connection layer extends underneath the perimeter metal seal ring.

12. The pixel driver chip of claim 10, wherein the plurality of landing pads includes a Vsense output pad, and the electrical connection is electrically connected with the Vsense output pad.

13. The pixel driver chip of claim 10, wherein the electrical connection is connected with the device region.

14. The pixel driver chip of claim 13, wherein the electrical connection is formed of a polycide material.

15. The pixel driver chip of claim 13, wherein the electrical connection is a doped region of the semiconductor substrate.

16. The pixel driver chip of claim 13, further comprising a second electrical connection extending to a second sidewall of the chip sidewalls.

17. The pixel driver chip of claim 16, further comprising a metal trace routing connected with the second electrical connection, wherein the metal trace routing and the second electrical connection are not connected with the device region.

18. The pixel driver chip of claim 17, wherein the electrical connection and the second electrical connection are both formed of a polycide material.

19. The pixel driver chip of claim 17, wherein the electrical connection and the second electrical connection are each doped regions of the semiconductor substrate.

20. The pixel driver chip of claim 17, wherein one of the electrical connection and the second electrical connection is formed of a polycide material, and one of the electrical connection and the second electrical connection is a doped region of the semiconductor substrate.
